(19) United States
(12) Patent Application Publication
(10) Pub. No.: US 2025/0060560 A1
(43) Pub. Date: Feb. 20, 2025

(54) MOTOR CONTROL CIRCUIT FOR LENS FOCUSING

(71) Applicant: TILTA INC., Burbank, CA (US)

(72) Inventors: Qianjin GENG, Shenzhen (CN); Wenping ZENG, Shenzhen (CN); Kefeng ZHOU, Shenzhen (CN)

(21) Appl. No.: 18/535,330

(22) Filed: Dec. 11, 2023

(30) Foreign Application Priority Data
Aug. 17, 2023 (CN) 2023222308828

(51) Int. Cl. G02B 7/09; G02B 7/02; H02K 11/22; H02K 11/26; H02K 11/27; H02K 11/33; H03K 17/00

(52) U.S. Cl. CPC G02B 7/09; G02B 7/023; H02K 11/22; H02K 11/26; H02K 11/27; H02K 11/33; H03K 17/002

(57) ABSTRACT

The present disclosure provides a motor control circuit for lens focusing. The circuit comprises a first chip unit, a second chip unit, and a motor drive unit. The first chip unit is communicatively connected to a handwheel for receiving handwheel signals. The second chip unit is connected to the first chip unit via a serial port. The motor drive unit is connected to the second chip unit and, upon receiving wheel signals from the first chip unit, controls the motor to rotate. This circuit achieves automatic control of lens parameters, enabling automatic and stable focusing by the motor, thereby improving shooting efficiency and convenience.

### CROSS-REFERENCE TO RELATED APPLICATIONS

The present Application for patent claims priority to and the benefit of pending Chinese Application No. 2023222308828, filed Aug. 17, 2023, and hereby expressly incorporated by reference herein as if fully set forth below in its entirety and for all applicable purposes.

### TECHNICAL FIELD

The present disclosure relates to the technical the field of electronic circuit technology and, more specifically, to a motor control circuit for lens focusing.

### INTRODUCTION

Currently, photographers need to adjust the focus and focal length of the lens to capture different images during the shooting process. Typically, this involves manually rotating the lens of the camera. However, camera equipment can be heavy, and continuous manual adjustments can lead to imprecise focusing and reduced shooting efficiency, affecting the overall quality of the captured images. Therefore, there is a need for an automatic and stable focusing control circuit to address the aforementioned technical issues.

### BRIEF SUMMARY

In view of the above challenges, the present disclosure provides a motor control circuit for lens focusing, which effectively addresses the issues of low shooting efficiency and inconvenience associated with manual adjustments. Compared to manual adjustments, this circuit achieves more precise and stable adjustment of lens parameters through automatic control.

To achieve the above objectives, the present disclosure adopts the following technical solutions:

The motor control circuit for lens focusing provided by the present disclosure comprises:

a first chip unit, communicatively connected to a handwheel for receiving handwheel signals;

a second chip unit, connected to the first chip unit via a serial port;

a motor drive unit, connected to the second chip unit, configured to control the motor to rotate upon receiving wheel signals from the second chip unit.

As an optional embodiment, the motor control circuit for lens focusing further comprising a power interface circuit and a voltage reduction circuit. A first end of the power interface circuit is connected to the voltage reduction circuit, and the voltage reduction circuit is connected to the first chip unit and the second chip unit for providing power. A second end of the power interface circuit is connected to the motor drive unit for providing power to the motor drive unit.

As an optional embodiment, the motor control circuit for lens focusing further comprising a first voltage reduction circuit and a second voltage reduction circuit. A first end of the first voltage reduction circuit is connected to the first end of the power interface circuit. A second end of the first voltage reduction circuit is connected to a first end of the second voltage reduction circuit. A second end of the second voltage reduction circuit is connected to the first chip unit.

As an optional embodiment, the motor control circuit for lens focusing further comprising a power interface switch circuit. The power interface circuit includes multiple power interface circuits. A first end of the power interface switch circuit is connected to a third end of one of the power interface circuits, and a second end of the power interface switch circuit is connected to a third end of another one of the power interface circuits for controlling power-on or power-off of any one of the power interface circuits.

As an optional embodiment, the motor control circuit for lens focusing further comprising a first power output switch circuit and a second power output switch circuit. The second end of both the first power output switch circuit and the second power output switch circuit is connected to an output end of the first voltage reduction circuit. The first end of the first power output switch circuit is connected to one of the power interface circuits, and the first end of the second power output switch circuit is connected to another one of the power interface circuits. The power interface switch circuit, the first power output switch circuit, and the second power output switch circuit cooperate to control the output of the power interface circuits.

As an optional embodiment, the motor control circuit for lens focusing further comprising a voltage acquisition circuit. The voltage acquisition circuit is connected to an input end of the voltage reduction circuit and is used to acquire input voltage.

As an optional embodiment, the second chip unit is also connected to a motor channel status indication circuit, and the motor channel status indication circuit is connected to the voltage reduction circuit.

As an optional embodiment, the second chip unit is also connected to a magnetic encoder circuit. The magnetic encoder circuit receives angle data and converts the angle data into electrical signals, allowing the second chip unit to control the motor's rotation based on the electrical signals.

As an optional embodiment, the motor control circuit for lens focusing further comprising a power current detection circuit connected to the motor drive unit. The power current detection circuit is used to detect current.

As an optional embodiment, the motor control circuit for lens focusing further comprising a camera interface circuit connected to the first chip unit. The camera interface circuit is also connected to the voltage reduction circuit and provides power and communication for the camera.

As an optional embodiment, the motor control circuit for lens focusing further comprising a keypad circuit. One end of the keypad circuit is connected to the second voltage reduction circuit, and the other end of the keypad circuit is connected to the first chip unit.

As an optional embodiment, the first chip unit further connects to a communication transceiver unit, wherein the communication transceiver unit is a 2.4 G communication interface.

The present utility model provides a motor control circuit for lens focusing. The circuit comprises a first chip unit, a second chip unit, and a motor drive unit. The first chip unit sends the signal from the handwheel to the second chip unit, which receives the signal and controls the motor rotation using the motor drive unit. The motor then drives the camera lens engaged with the motor, achieving automatic adjustment of camera parameters. In this manner, automatic control of lens parameters improves shooting efficiency and convenience. It also provides more accurate camera lens adjustment compared to manual adjustment.

To make the objectives, features, and advantages of this invention more clearly understood, exemplary embodiments and accompanying drawings are provided below for detailed explanation.

### BRIEF DESCRIPTION OF THE DRAWINGS

For a clearer explanation of the technical solutions of exemplary embodiments of the present disclosure, brief introductions to the drawings required for use in the embodiments will be provided below. It should be understood that the following drawings only illustrate some embodiments of the present disclosure and should not be considered as limiting the scope of the present disclosure.

FIG. 1 is a schematic diagram of the circuit block of the motor control circuit for lens focusing provided by the present disclosure.

FIG. 2 is a circuit diagram of the first chip unit provided by the present disclosure.

FIG. 3 is a circuit diagram of the second chip unit provided by the present disclosure.

FIG. 4 is a circuit diagram of the power interface switch circuit provided by the present disclosure.

FIG. 5 is a circuit diagram of power interface circuit one provided by the present disclosure.

FIG. 6 is a circuit diagram of power interface circuit two provided by the present disclosure.

FIG. 7 is a circuit diagram of the first voltage reduction circuit provided by the present disclosure.

FIG. 8 is a circuit diagram of the second voltage reduction circuit provided by the present disclosure.

FIG. 9 is a circuit diagram of the keypad circuit provided by the present disclosure.

FIG. 10 is a circuit diagram of the power current detection circuit provided by the present disclosure.

FIG. 11 is a circuit diagram of the motor channel status indication circuit provided by the present disclosure.

FIG. 12 is a circuit diagram of the camera interface circuit provided by the present disclosure.

FIG. 13 is a circuit diagram of the 2.4 G wireless channel provided by the present disclosure.

FIG. 14 is a circuit diagram of the motor drive unit provided by the present disclosure.

FIG. 15 is a circuit diagram of the first power output switch circuit and the second power output switch circuit provided by the present disclosure.

FIG. 16 is a schematic diagram of a motor in an embodiment.

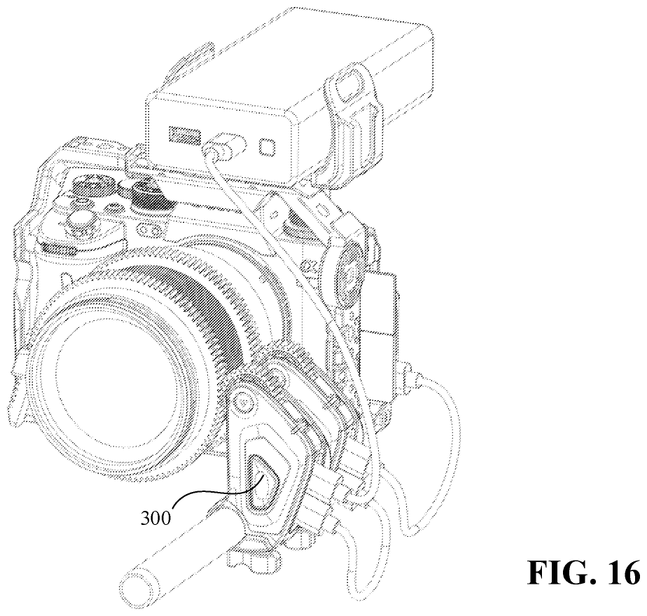

FIG. 17 is a schematic diagram of a handwheel in an embodiment.

### MAJOR COMPONENT SYMBOL DESCRIPTIONS

100—First chip unit; 110—Second chip unit; 120—Motor drive unit; 130—Voltage reduction circuit; 140—Voltage acquisition circuit; 150—Power interface circuit; 160—First voltage reduction circuit; 170—Power interface switch circuit; 200—Camera interface circuit; 210—keypad circuit; 220—Second voltage reduction circuit; 230—Power current detection circuit; 240—Motor channel status indication circuit; 250—Magnetic encoder circuit; 260—Communication transceiver unit; 270—First power output switch circuit; 280—Second power output switch circuit; 290—handwheel; 300—motor.

### DETAILED DESCRIPTION

The following detailed description provides an explanation of specific embodiments of the present disclosure, where identical or similar reference numerals represent identical or similar components or components with identical or similar functions throughout.

It is vital to recognize that the specific embodiments delineated below are solely aimed at elucidating the present disclosure and do not seek to confine its scope.

In the following sections, a clear and comprehensive description of the technical solutions in the present disclosure is provided, in conjunction with the accompanying figures. It should be noted that the embodiments described herein represent only a portion of the present disclosure's embodiments, rather than the entirety of them. Typically, the components of the present disclosure embodiments depicted and illustrated in these figures can be arranged and designed in various configurations. Therefore, the detailed description of the embodiments of the present disclosure provided in the figures is not intended to limit the scope of protection for the present disclosure but serves to illustrate selected embodiments of the present disclosure. Based on the embodiments of the present disclosure, all other embodiments that can be obtained by those skilled in the art without inventive effort are also encompassed within the scope of protection for the present disclosure.

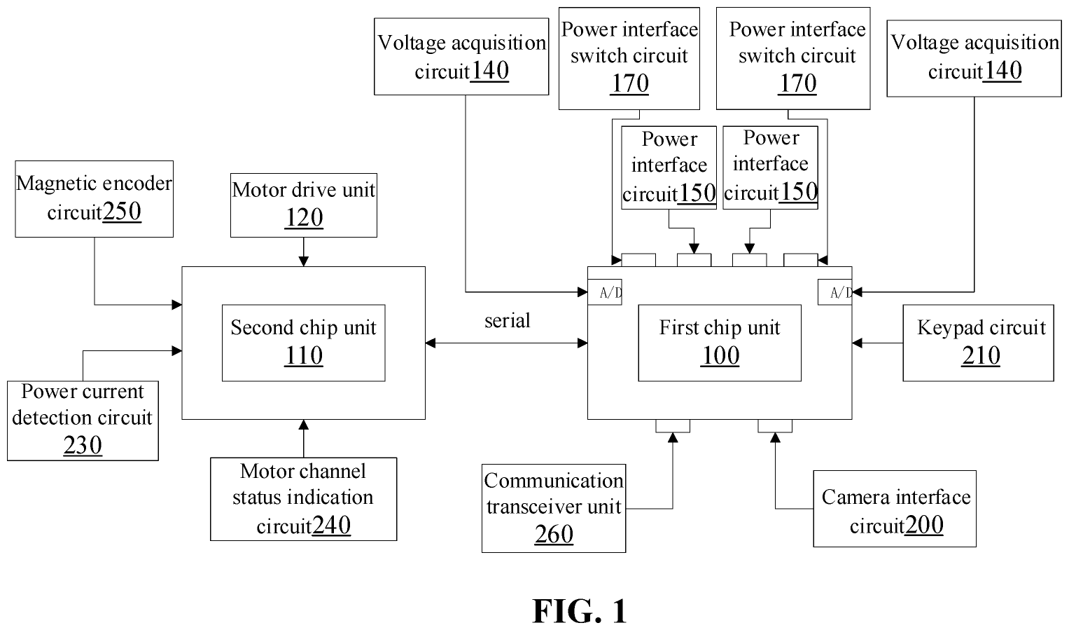

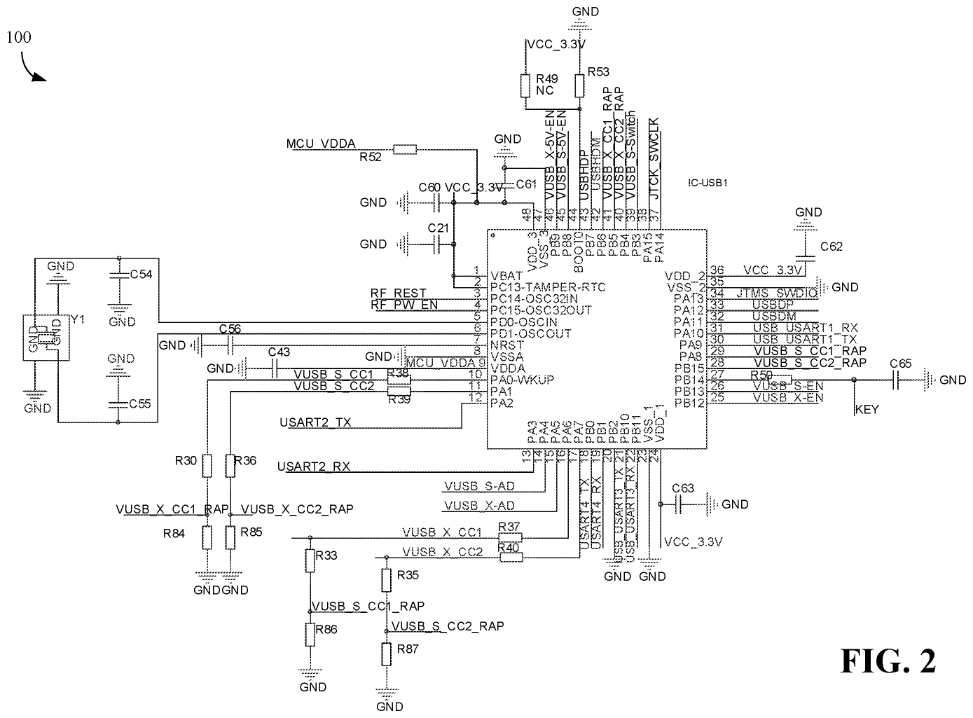

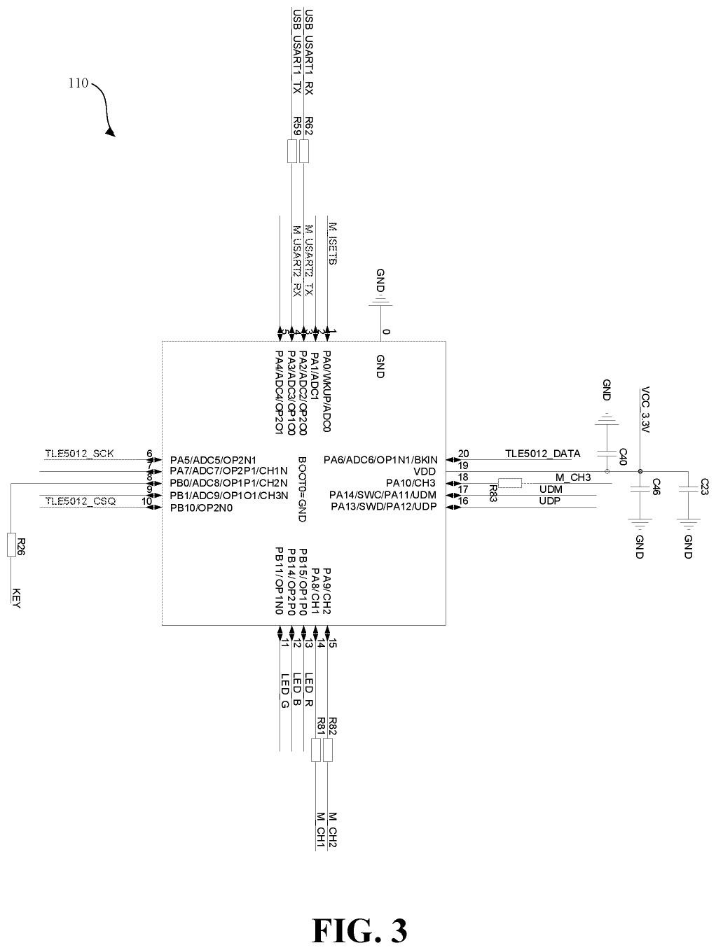

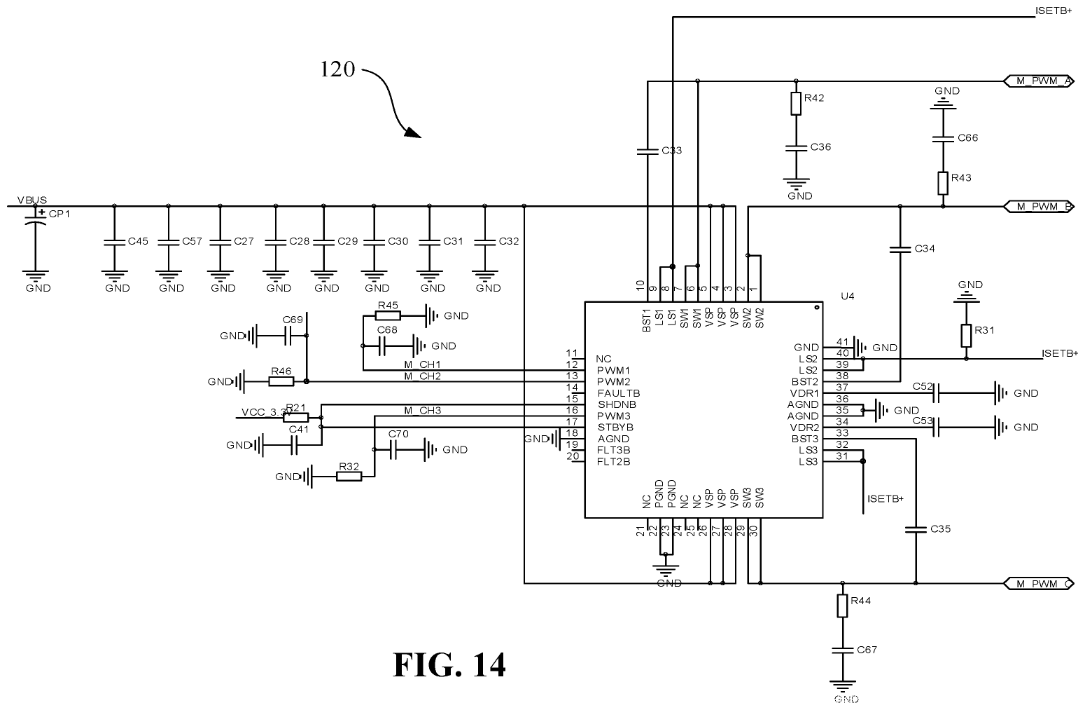

Referring to FIGS. 1, 2, 3, 14 and 17, the present disclosure provides a motor control circuit for lens focusing, wherein the motor control circuit comprises:

A first chip unit 100, communicatively connected to a handwheel 290 for receiving handwheel 290 signals;

A second chip unit 110, connected to the first chip unit 100 via a serial port;

The motor drive unit 120 is connected to the second chip unit 110 and, upon receiving wheel signals from the first chip unit 100, controls the motor to rotate.

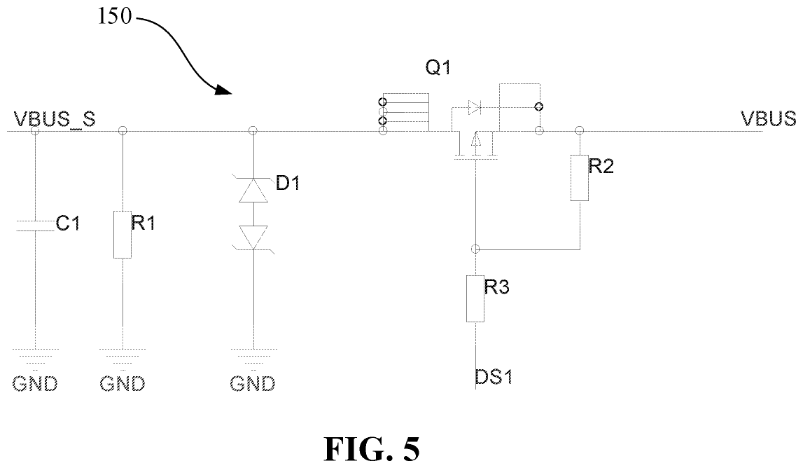

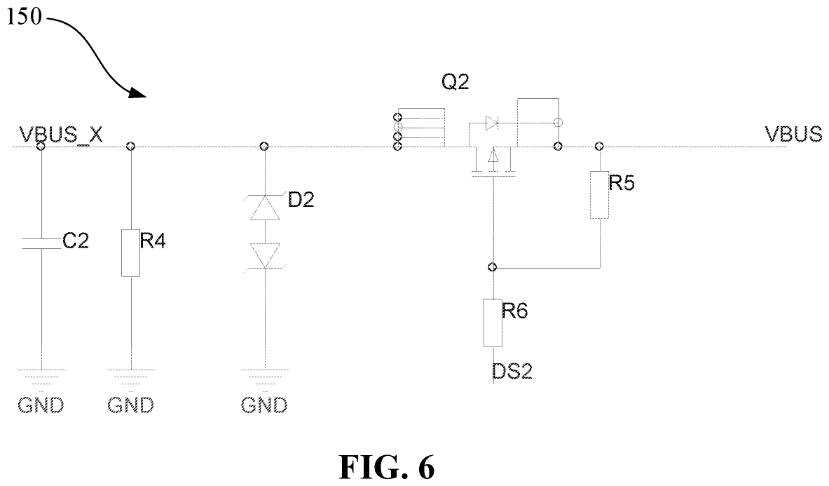

Referring to FIGS. 1, 5-7, and 14, the motor control circuit further comprising a power interface circuit 150 and a voltage reduction circuit 130. A first end of the power interface circuit 150 is connected to the voltage reduction circuit 130, which is connected to the first chip unit 100 and the second chip unit 110 for providing power. A second end of the power interface circuit 150 is connected to the motor drive unit 120 for providing power to the motor drive unit 120. In this embodiment, the motor drive unit 120 is mainly used to drive the motor 300 to rotate, and in this application, it is mainly a servo motor drive.

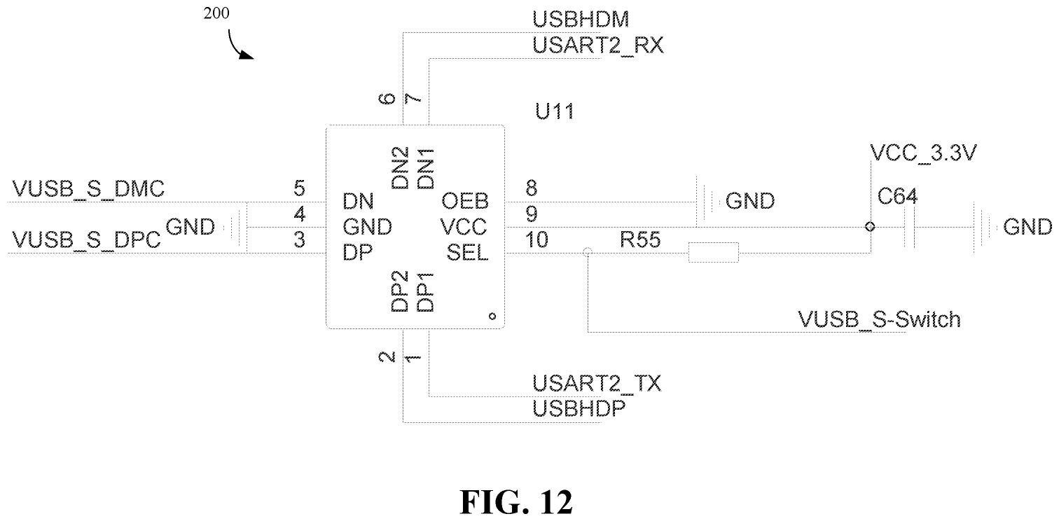

Referring to FIG. 12, the motor control circuit further comprising a camera interface circuit 200 connected to the first chip unit 100. The camera interface circuit 200 is also connected to the port on the camera and provides power and communication for the camera. It controls the adjustment of camera parameters by controlling the rotation of the camera lens. It should be noted that the communication interface is not limited in this embodiment, for example, it can be connected to the camera via USB or a serial port.

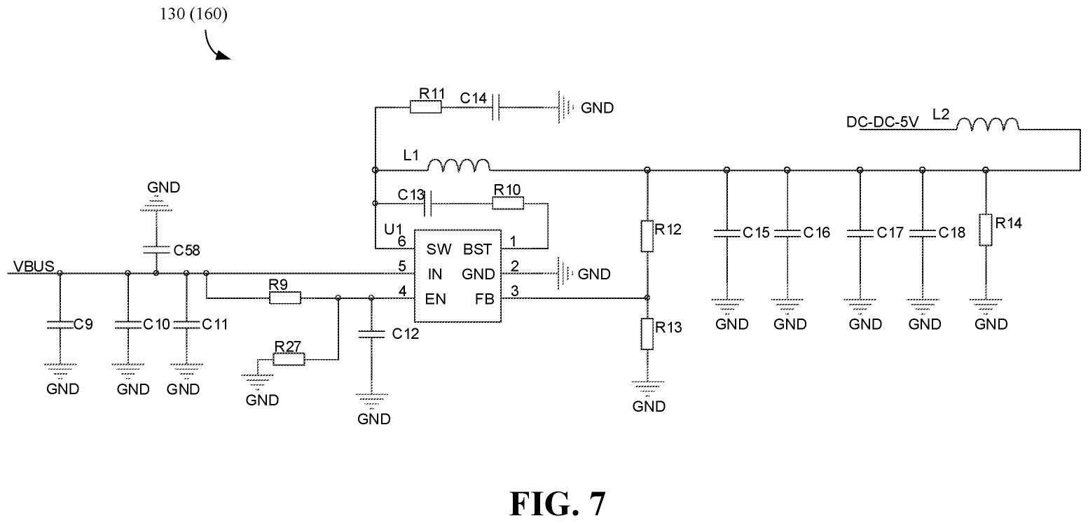

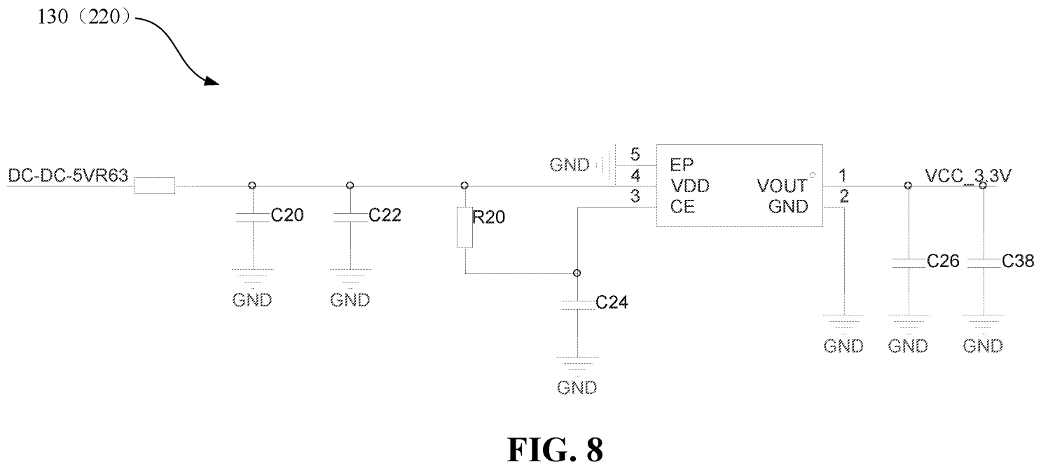

Referring to FIGS. 7 and 8, specifically, the voltage reduction circuit 130 comprises a first voltage reduction circuit 160 and a second voltage reduction circuit 220. A first end of the first voltage reduction circuit 160 is connected to the first end of the power interface circuit. 150 A second end of the first voltage reduction circuit 160 is connected to the first end of the second voltage reduction circuit 220. The second end of the second voltage reduction circuit 220 is connected to the first chip unit 100.

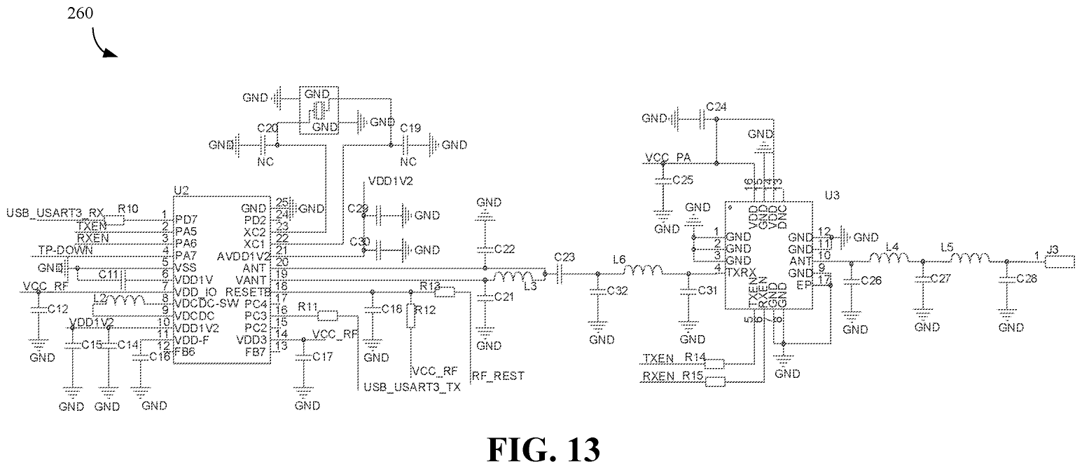

Referring to FIGS. 1, 10, 11, and 13, the motor control circuit further comprising a power current detection circuit 230 connected to the second chip unit 110. The power current detection circuit 230, which is connected to the motor 300, is used to detect current. The second chip unit 110 is also connected to a motor channel status indication circuit 240, which is connected to the second voltage reduction circuit 220. The second chip unit 110 is also connected to a magnetic encoder circuit 250, which receives angle data and converts the angle data into electrical signals, allowing the second chip unit 110 to control the motor's rotation based on the electrical signals. The motor drive unit 120 is a servo motor in this embodiment. The first chip unit 100 is also connected to a communication transceiver unit 260, which is a 2.4 G communication interface that communicates wirelessly with the handwheel 290. In this embodiment, the magnetic encoder can be a commercially available product.

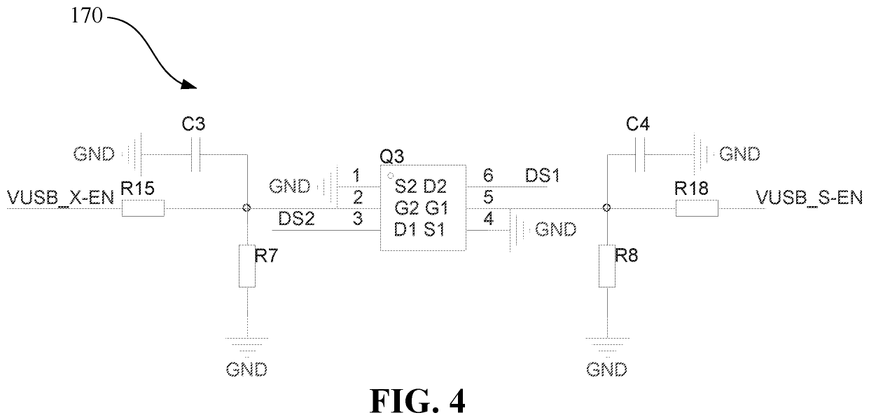

It should be noted that, as shown in FIGS. 1, 4, 5, 6 and 7, the first chip unit 100 includes a clock circuit and a filter circuit. The first chip unit 100 is primarily powered through a USB interface. The second chip unit 110 controls the motor drive unit 120 to drive the motor. The first chip unit 100 is equipped with a 2.4 G communication interface for communicating with the handwheel 290 to receive handwheel 290 rotation signals. The second chip unit 110 is connected to the motor drive unit 120, and when the motor drive unit 120 is connected to the handwheel 290 for communication, the second chip unit 110 receives the rotation signal, which is equivalent to receiving the motor rotation angle signal from the handwheel 290. When the first chip unit 100 sends a rotation signal to the second chip unit 110, the second chip unit 110 controls the servo motor to rotate based on the received motor rotation angle signal, which is achieved by driving the servo motor to rotate through pulse signals. This ensures stable automatic motor control and thus achieves stable autofocus. The first chip unit 100 is connected to two power interface circuits 150, and the input ends of the power interface circuits 150 are equipped with voltage acquisition circuits 140 for measuring the input voltage of the power interface circuits 150. The power interface circuits (150) are equipped with power interface switch circuits 170, and when it is necessary to turn off a power interface circuit 150 with lower current, this specific power interface circuit 150 can be turned off through the power interface switch circuit 170. By using the power interface circuits 150 for power input, continuous operation of the motor drive unit 120 is enabled, and the voltage level of the input power can be determined by measuring the voltage using the voltage acquisition circuits 140 to acquire the current level of these two circuit paths. The power interface power interface switch circuits 170 select the high-voltage power interface circuit 150 by closing the power interface circuit 150 with a lower current for power input. This connection between the circuits improves the circuit operation's stability.

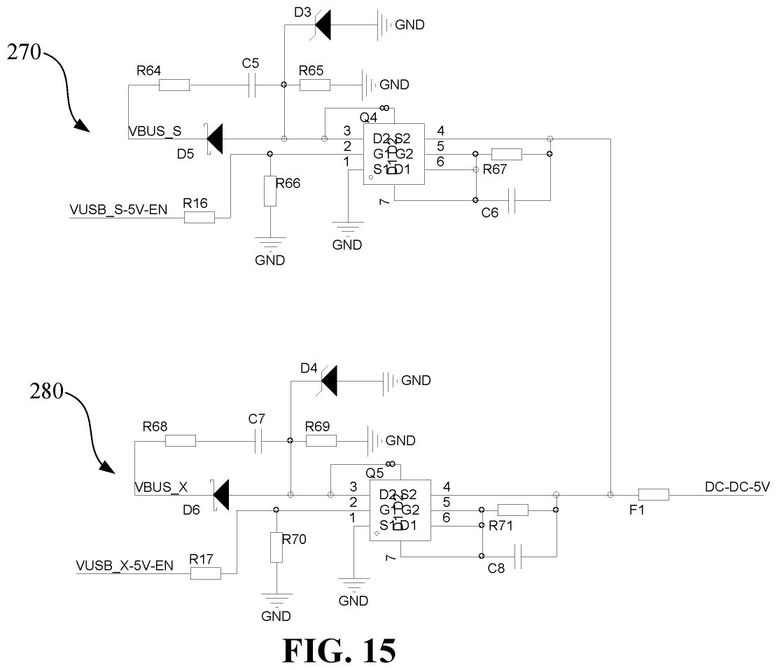

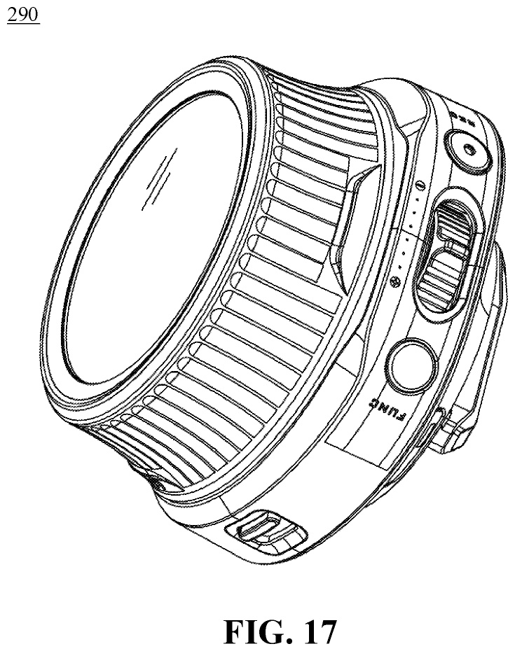

In this embodiment, referring to FIGS. 15 and 17, the motor control circuit further comprising a first power output switch circuit 270 and a second power output switch circuit 280. The second end of both the first power output switch circuit 270 and the second power output switch circuit 280 is connected to an output end of the first voltage reduction circuit 160. The first end of the first power output switch circuit 270 is connected to one of the power interface circuits 150, and the first end of the second power output switch circuit 280 is connected to another power interface circuit 150. The power interface switch circuit 170, the first power output switch circuit 270, and the second power output switch circuit 280 cooperate to control the input and output of the power interface circuit 150. In this embodiment, when it is necessary to adjust different parameters of the lens, multiple motor 300 drives are required. This embodiment provides an example of two motors 300. Each motor has two power interface circuits 150. Between the two power interface circuits 150 of each motor, there is a power interface switch circuit 170. The front ends of the two power interface circuits 150 are respectively connected to the first output switch circuit 270 and the second output switch circuit 280. The two power interface circuits 150 at the rear end are interconnected. For the current motor, the first power interface circuit 150 is connected to an external power source, and the second power interface circuit 150 can be connected to power the camera or the first power interface circuit 150 of the next-level motor.

When the current motor communicates with the next-level motor, control of the power interface switch circuit 170 is used to determine whether the first power interface circuit 150 of the current motor outputs a modulated voltage to the first power interface circuit 150 of the next-level motor. In other words, if the first power interface circuit 150 inputs a voltage of N, then the second power interface circuit 150 outputs a voltage of N to the next-level motor. When the current motor fails to recognize the next-level motor, the second end of the first power output switch circuit 270 is connected to the output end of the first voltage reduction circuit 160. At this time, the first output switch circuit 270 controls the first power interface circuit 150 of the current motor to output a modulated voltage via the second power interface circuit 150. In this embodiment, the modulated voltage is specifically 5V. In summary, this embodiment ensures the stability of the motor drive control circuit by controlling the output of the power interface circuits 150.

In another embodiment, when the second power interface circuit 150 of the current motor is connected to an external power source, the first power interface circuit 150 of the current motor can be connected to power the camera or the first power interface circuit 150 of the next-level motor. The process is the same as described in the previous embodiment, with the difference being the control of the power interface switch circuit 170 (when the current motor communicates with the next-level motor) and the second output switch circuit 280 (when the current motor fails to recognize the next-level motor). It determines if the second power interface circuit 150 of the current motor is outputting unmodulated or modulated voltage via the first power interface circuit 150. Therefore, further elaboration is not provided in this embodiment.

Referring again to FIG. 1, in one feasible embodiment, the voltage acquisition circuit 140 includes capacitors and resistors with different parameters, and the power interface switch circuit 170 includes multiple resistors, capacitors, and switch transistors Q3. The power interface switch circuit 170 is connected to a voltage acquisition circuit 140 at both ends. The first and second branch circuits of the power interface circuit 150 each contain numerous parallel resistors, capacitors, and power switch transistor Q1.

Referring again to FIGS. 1, 4-8, in one feasible embodiment, the input end of the power interface circuits 150 includes a voltage acquisition circuit 140, and one end of the power interface circuits 150 is divided into two branches, namely, the first branch and the second branch. One branch is connected to drive the motor drive unit 120 to supply power to the motor drive unit 120. The voltage reduction circuit 130 includes the first voltage reduction circuit 160 and the second voltage reduction circuit 220. The other branch of the power interface circuits 150 is connected to the first voltage reduction circuit 160 to reduce the voltage to an adaptable voltage, such as reducing it to 5V for powering the camera. The other end of the first voltage reduction circuit 160 is connected to the second voltage reduction circuit 220 to further reduce the voltage to an adaptable voltage, such as reducing it to 3.3V, for powering the internal circuits, namely, the first chip unit 100 and the various circuits connected to the second chip unit 110. It should be noted that the circuit structures of the first branch and the second branch of the power interface circuits 150 are the same, while the circuit structures of the first voltage reduction circuit 160 and the second voltage reduction circuit 220 are different. The first voltage reduction circuit 160 includes a filtering circuit and multiple parallel capacitors, while the second voltage reduction circuit 220 includes multiple parallel circuits.

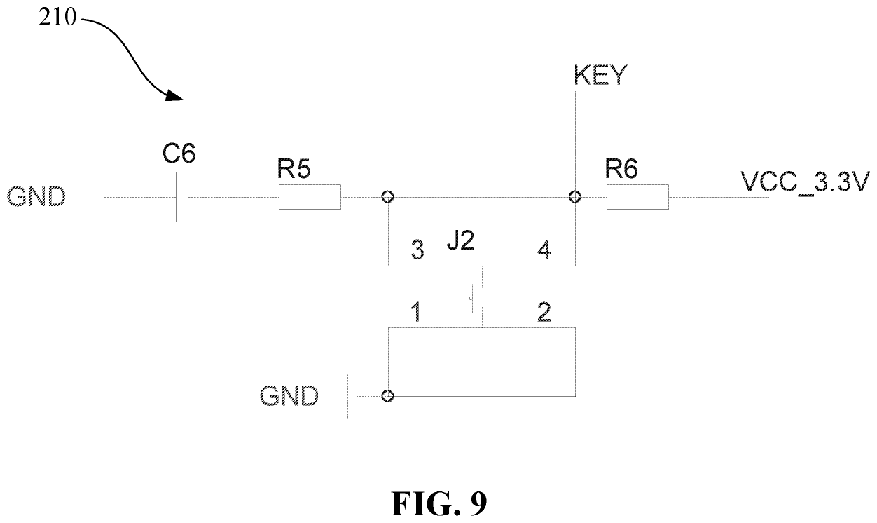

Referring again to FIG. 9, in one feasible embodiment, the keypad circuit 210 is connected to 3.3V at one end, which can be connected to 3.3V through the second voltage reduction circuit 220. The other end is connected to the first chip unit 100. By pressing the keypad, the first chip unit 100 receives a signal indicating a change in the motor's identification number, thereby controlling the signal change of the motor 300.

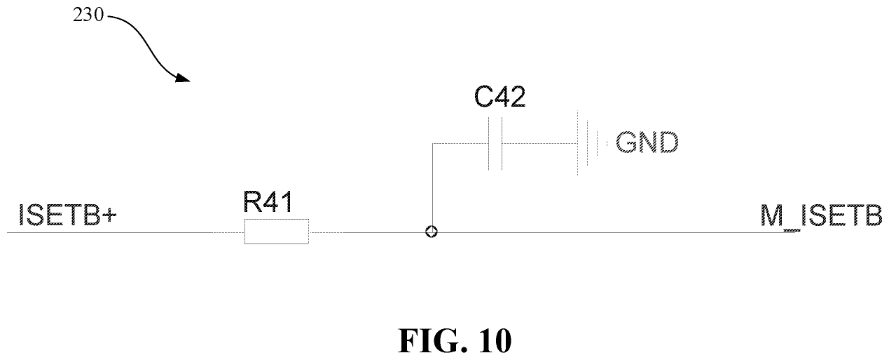

Referring again to FIG. 10, in a feasible embodiment, the second chip unit 110 is equipped with a power current detection circuit 230. The other end of the power current detection circuit 230 is connected to the motor drive unit 120 to capture and monitor the current, thus serving as a safeguard against motor overheating or damage.

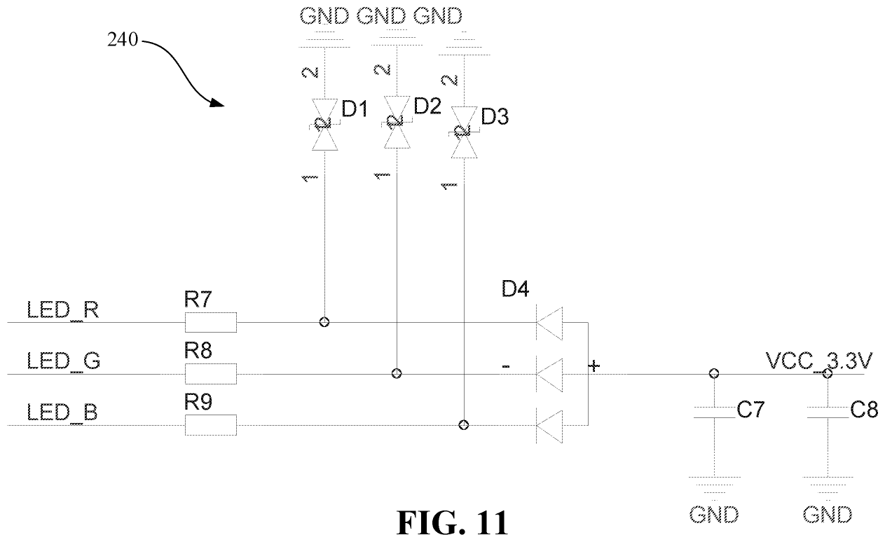

Furthermore, revisiting FIGS. 11 and 17 in another feasible embodiment, the second chip unit 110 is also linked to a motor channel status indication circuit 240. One end of the motor channel status indication circuit 240 is connected to a 3.3V voltage source, which can be accessed via the second voltage reduction circuit 220. This configuration enables the adjustment of various camera parameters by distinct numbered motor drive units 120. If during installation, a mismatch is detected between the motor engaged at the lens parameter adjustment location and its assigned parameter, the motor channel status indication circuit 240 can be employed to alter the motor's identification number. For example, if there are four motors 300 with unique numbers and the need arises for motor 300 No. 2, the second chip unit 110 can manipulate the logic level at position 2 (where motor No. 2 is located) to lower it, thereby enabling signal transmission through that channel. Other numbered channels, remaining at a high logic level, will remain inactive. Consequently, the motor 300 will correspond to identification number 2.

Referring again to FIG. 1, in a feasible embodiment, the second chip unit 110 is also linked to a magnetic encoder circuit 250. This magnetic encoder circuit 250 receives angle data and converts it into electrical signals. This enables the second chip unit 110 to control the motor's 300 rotation by a corresponding angle based on the electrical signal received. The angle data is inherently related to the handwheel 290's rotation signal. To elaborate, the magnetic encoder circuit 250 processes the received angle data into electrical signals and transmits them to the second chip unit 110. This enables the second chip unit 110 to control the motor's rotation to the desired angle through the motor drive unit 120. It is important to note that the angle data received is correlated with the handwheel 290's rotation signal.

It should be understood that within the circuit, the first chip unit 100 communicates wirelessly with the handwheel 290 using a 2.4 GHz connection. Upon receiving the handwheel 290 signal, the first chip unit 100 generates a potential difference via the motor drive unit 120. This potential difference activates the motor, causing it to rotate. Consequently, the motor engages with the camera lens, resulting in the adjustment of camera parameters. This is achieved by configuring the first chip unit 100, second chip unit 110, power interface circuit 150, and voltage reduction circuit 130. The power interface circuit 150 routes power to the motor drive unit 120, ensuring a stable power supply. The voltage reduction circuit 130 facilitates the provision of stable power to the first chip unit 100 and the second chip unit 110. Furthermore, the power interface circuit 150 manages power supply to the motor drive unit 120 in a stable manner to control its rotation. The first chip unit 100 is equipped with several power interface circuits 150, whose input end includes a voltage acquisition circuit 140 that measures the input voltage of the power source. By employing multiple power interface circuits 150, the input voltage is continuously provided to the motor, thus enabling its uninterrupted operation. Additionally, the voltage acquisition circuit 140 is integrated into the power interface circuit 150 to monitor the input voltage level. This allows for the assessment of current magnitude across the two circuit channels. The power interface switch circuit 170 selectively deactivates the less significant power interface circuit 150 channels, prioritizing those with higher voltage levels. In this manner, automatic control of lens parameters improves shooting efficiency and convenience. It also provides more accurate camera lens adjustment compared to manual adjustment.

To make the objectives, technical solutions, and advantages of the present disclosure embodiment clearer, the above description combines the figures in the present disclosure embodiment to provide a clear and complete description of the technical solutions in the present disclosure embodiment. It is apparent that the described embodiments are just part of the present disclosure embodiment, not all embodiments. Typically, the components of the embodiments described and shown in the figures can be arranged and designed in various configurations.

Therefore, the detailed description of the embodiments of the present disclosure provided in the figures is not intended to limit the scope of the present disclosure being claimed, but merely represents selected embodiments of the present disclosure. Based on the embodiments of the present disclosure, all other embodiments obtained by those skilled in the art without making creative efforts belong to the scope of protection of the present disclosure.

What is claimed is:

1. A motor control circuit for lens focusing, characterized by comprising:
a first chip unit, communicatively connected to a handwheel for receiving handwheel signals;
a second chip unit, connected to the first chip unit via a serial port; and
a motor drive unit, connected to the second chip unit, configured to control a motor to rotate upon receiving handwheel signals from the first chip unit.

2. The motor control circuit for lens focusing according to claim 1, further comprising:
a power interface circuit; and
a voltage reduction circuit,
wherein a first end of the power interface circuit is connected to the voltage reduction circuit,
the voltage reduction circuit is connected to the first chip unit and the second chip unit for providing power, and
a second end of the power interface circuit is connected to the motor drive unit for providing power to the motor drive unit.

3. The motor control circuit for lens focusing according to claim 2, wherein the voltage reduction circuit comprises:
a first voltage reduction circuit; and
a second voltage reduction circuit,
wherein a first end of the first voltage reduction circuit is connected to the first end of the power interface circuit,
wherein a second end of the first voltage reduction circuit is connected to the first end of the second voltage reduction circuit, and
wherein a second end of the second voltage reduction circuit is connected to the first chip unit.

4. The motor control circuit for lens focusing according to claim 3, further comprising:
a power interface switch circuit,
wherein the power interface circuit includes multiple power interface circuits, and
wherein a first end of the power interface switch circuit is connected to a third end of one of the power interface circuits, and a second end of the power interface switch circuit is connected to a third end of another one of the power interface circuits for controlling power-on or power-off of any one of the power interface circuits.

5. The motor control circuit for lens focusing according to claim 4, further comprising:
a first power output switch circuit; and
a second power output switch circuit,
wherein a second end of both the first power output switch circuit and the second power output switch circuit is connected to an output end of the first voltage reduction circuit,
wherein a first end of the first power output switch circuit is connected to one of the power interface circuits,
wherein a first end of the second power output switch circuit is connected to another one of the power interface circuits,
wherein the power interface switch circuit, the first power output switch circuit, and the second power output switch circuit cooperate to control an output of the power interface circuits.

6. The motor control circuit for lens focusing according to claim 2, further comprising:
a voltage acquisition circuit connected to an input end of the voltage reduction circuit and configured to acquire an input voltage.

7. The motor control circuit for lens focusing according to claim 2, wherein the second chip unit is connected to a motor channel status indication circuit, which is connected to the voltage reduction circuit.

8. The motor control circuit for lens focusing according to claim 1,
wherein the second chip unit is connected to a magnetic encoder circuit,
wherein the magnetic encoder circuit is configured to receive angle data and convert the angle data into electrical signals, enabling the second chip unit to control a rotation of the motor based on the electrical signals.

9. The motor control circuit for lens focusing according to claim 1, further comprising a power current detection circuit connected to the second chip unit, the power current detection circuit, which is connected to the motor, is configured to detect a current.

10. The motor control circuit for lens focusing according to claim 3, further comprising a camera interface circuit connected to the first chip unit, wherein the camera interface circuit is connected to the first voltage reduction circuit and is configured to provide power and communication for a camera.

11. The motor control circuit for lens focusing according to claim 10, further comprising a keypad circuit, wherein a first end of the keypad circuit is connected to the second voltage reduction circuit, and a second end of the keypad circuit is connected to the first chip unit.
